(19) United States
(12) Patent Application Publication
(10) Pub. No.: US 2025/0169064 A1
(43) Pub. Date: May 22, 2025

(54) SEMICONDUCTOR DEVICES

(71) Applicant: Samsung Electronics Co., Ltd., Suwon-si (KR)

(72) Inventors: Bitna Kim, Suwon-si (KR); Jinbum Kim, Suwon-si (KR); Kyeonggyu Lee, Suwon-si (KR); Sunguk Jang, Suwon-si (KR); Sunghwan Jang, Suwon-si (KR); Wonhee Choi, Suwon-si (KR)

(21) Appl. No.: 18/735,338

(22) Filed: Jun. 6, 2024

(30) Foreign Application Priority Data
Nov. 20, 2023 (KR) 10-2023-0160627

(51) Int. Cl. H10B 12/00

(52) U.S. Cl. CPC H10B 12/482; H10B 12/0335; H10B 12/315

(57) ABSTRACT

A semiconductor device includes a bit line on a substrate, a channel on the bit line, a first gate structure on a first sidewall of the channel, a contact structure between the bit line and the channel, the contact structure contacting the bit line and the channel, the contact structure including: a first contact including a semiconductor material doped with first impurities, the first impurities including a first diffusion coefficient, and a second contact on the first contact, the second contact contacting the first contact, the second contact including a semiconductor material doped with second impurities, the second impurities including a second diffusion coefficient, the second diffusion coefficient being less than the first diffusion coefficient, and a capacitor on and electrically connected to the channel.

### CROSS-REFERENCE TO RELATED APPLICATION

This application claims priority under 35 U.S.C. § 119 to Korean Patent Application No. 10-2023-0160627 filed on Nov. 20, 2023 in the Korean Intellectual Property Office, the disclosure of which is hereby incorporated by reference in its entirety.

### TECHNICAL FIELD

Example embodiments of the present disclosure relate to a semiconductor device. More particularly, example embodiments of the present disclosure relate to a memory device including a vertical channel.

### BACKGROUND

In order to improve an integration degree of a semiconductor device, a vertical channel memory device including a vertical channel transistor has been developed. The vertical channel transistor may include a bit line, a channel and a capacitor, and a contact may be interposed between the bit line and the channel. The characteristics of the capacitor may be inhibited due to a heat treatment process involved in forming the contact.

### SUMMARY

Example embodiments provide a semiconductor device having improved characteristics.

According to example embodiments, there is provided a semiconductor device. The semiconductor device may include a bit line on a substrate, the bit line extending in a first direction substantially parallel to an upper surface of the substrate, a channel on the bit line, the channel extending in a third direction substantially perpendicular to the upper surface of the substrate, a first gate structure on a first sidewall of the channel, the first gate structure extending in a second direction, the second direction substantially parallel to the upper surface of the substrate and intersecting the first direction, a contact structure between the bit line and the channel, the contact structure contacting the bit line and the channel, the contact structure including: a first contact including a semiconductor material doped with first impurities, the first impurities including a first diffusion coefficient, and a second contact on the first contact, the second contact contacting the first contact, the second contact including a semiconductor material doped with second impurities, the second impurities including a second diffusion coefficient, the second diffusion coefficient being less than the first diffusion coefficient, and a capacitor on and electrically connected to the channel.

According to example embodiments, there is provided a semiconductor device. The semiconductor device may include a bit line on a substrate, the bit line extending in a first direction substantially parallel to an upper surface of the substrate, a contact structure on the bit line, the contact structure including a first contact and a second contact that contact each other, the first contact including a first semiconductor material doped with first impurities, the second contact including a second semiconductor material doped with second impurities, the first and second impurities being different from each other, a channel on and contacting the contact structure, a first gate structure on a first sidewall of the channel and a second gate structure on a second sidewall of the channel, each of the first gate structure and the second gate structure extending in a second direction substantially parallel to the upper surface of the substrate and intersecting the first direction, and a capacitor on and electrically connected to contacting the channel, where a width of the contact structure in the first direction decreases from the upper surface of the substrate towards the capacitor, and where a width of the channel in the first direction decreases from the upper surface of the substrate towards the capacitor.

According to example embodiments, there is provided a semiconductor device. The semiconductor device may include a bit line on a substrate, the bit line extending in a first direction substantially parallel to an upper surface of the substrate, a contact structure on the bit line, the contact structure including: a first contact including a semiconductor material doped with first impurities including a first diffusion coefficient, and a second contact on and contacting the first contact, the second contact including a semiconductor material doped with second impurities including a second diffusion coefficient that is less than the first diffusion coefficient, a channel on and contacting the contact structure, the channel extending in a vertical direction substantially perpendicular to the upper surface of the substrate, a first gate structure and a second gate structure on a first sidewall and a second sidewall of the channel, respectively, the first and second sidewalls of the channel facing each other in the first direction, each of the first gate structure and the second gate structure extending in a second direction substantially parallel to the upper surface of the substrate and intersecting the first direction, and a capacitor on and electrically connected to the channel.

In a method of forming the semiconductor device in accordance with example embodiments, the capacitor may be formed after the contact structure, and thus, the characteristics of the capacitor may not deteriorate or be inhibited due to a heat treatment process involved in forming the contact structure.

The contact structure may include the first contact and the second contact that are sequentially stacked, and the diffusion coefficient of the second impurities of the second contact may be smaller than the diffusion coefficient of the first impurities of the first contact. Therefore, the first impurities of the first contact may inhibit or be prevented from diffusing into the channel during the heat treatment process.

In addition, the contact structure may be formed by forming an epitaxial layer having a plate shape through an epitaxial process and performing an etching process thereon. Accordingly, the contact structure may be formed to have an even surface, thereby reducing or preventing defects in subsequent processes.

### BRIEF DESCRIPTION OF THE DRAWINGS

FIGS. 1, 2, and 3 are a plan view and cross-sectional views illustrating a semiconductor device in accordance with example embodiments.

FIGS. 4, 5, 6, 7, 8, 9, 10, 11, 12, 13, 14, 15, 16, 17, 18, 19, 20, 21, 22, 23, 24, 25, 26 and 27 are plan views and cross-sectional views illustrating a method of manufacturing a semiconductor device in accordance with example embodiments.

FIG. 28 is a cross-sectional view illustrating a semiconductor device in accordance with example embodiments.

FIGS. 29 and 30 are cross-sectional views illustrating a semiconductor device in accordance with example embodiments.

### DETAILED DESCRIPTION

The above and other aspects and features of a semiconductor device and a method of manufacturing the same in accordance with example embodiments will become readily understood from detail descriptions that follow, with reference to the accompanying drawings. It will be understood that, although the terms “first,” “second,” and/or “third” may be used herein to describe various materials, layers (films), regions, electrodes, pads, patterns, structures and processes, these materials, layers (films), regions, electrodes, pads, patterns, structures and processes should not be limited by these terms. These terms are only used to distinguish one material, layer (film), region, electrode, pad, pattern, structure and process from another material, layer (film), region, electrode, pad, pattern, structure and process. Thus, a first material, layer (film), region, electrode, pad, pattern, structure and process discussed below could be termed a second or third material, layer (film), region, electrode, pad, pattern, structure and process without departing from the teachings of inventive concepts.

To clarify the present disclosure, parts that are not connected with the description will be omitted, and the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements and/or components, but do not preclude the presence or addition of one or more other features, steps, operations, elements, components and/or groups thereof. The term “and/or” includes any and all combinations of one or more of the associated listed items. The term “connected” may be used herein to refer to a physical and/or electrical connection and may refer to a direct or indirect physical and/or electrical connection. Components or layers described with reference to “overlap” in a particular direction may be at least partially obstructed by one another when viewed along a line extending in the particular direction or in a plane perpendicular to the particular direction.

Hereinafter, in the specification (and not necessarily in the claims), two directions that are substantially perpendicular to each other among horizontal directions, which are substantially parallel to an upper surface of each of first to third substrates, may be referred to as first and second directions D1 and D2, respectively, and a vertical direction substantially perpendicular to the upper surface of the each of first to third substrates may be referred to as a third direction D3. In example embodiments, the first and second directions D1 and D2 may be orthogonal to each other. Each of the first to third directions D1, D2 and D3 may represent not only a direction shown in the drawing, but also a reverse or opposite direction to the given direction.

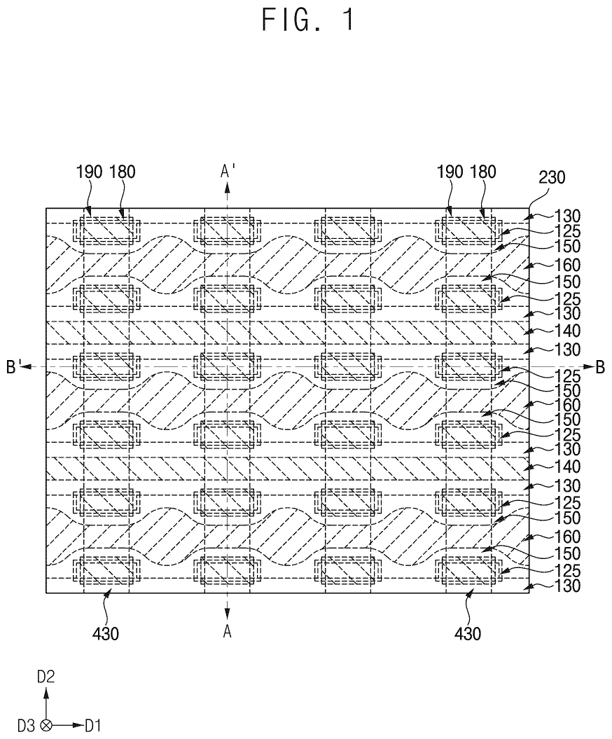

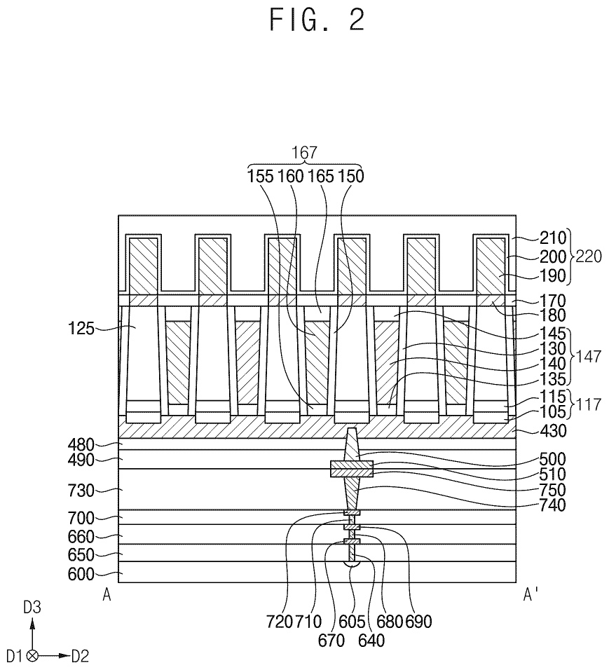

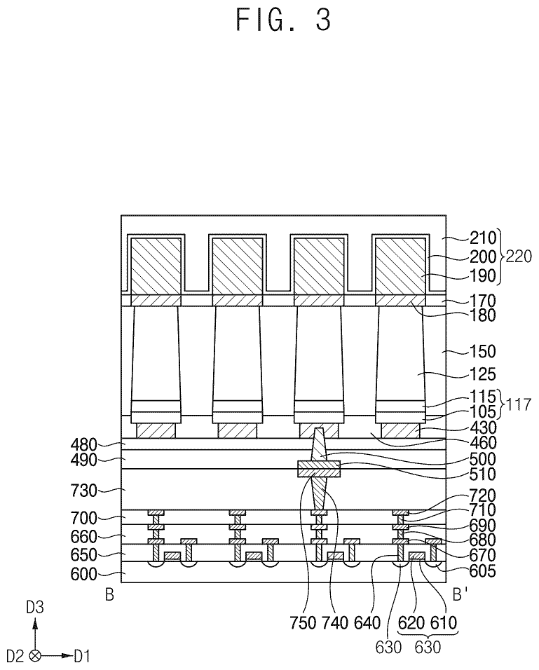

FIGS. 1 to 3 are a plan view and cross-sectional views illustrating a semiconductor device in accordance with example embodiments. Specifically, FIG. 1 is the plan view, FIG. 2 is a cross-sectional view taken along line A-A′ of FIG. 1, and FIG. 3 is a cross-sectional view taken along line B-B′ of FIG. 1.

Referring to FIGS. 1 to 3, the semiconductor device may include a lower circuit pattern, a bit line 430, first and second gate structure 147 and 167, a contact structure 117, a channel 125, a landing pad 180 and a capacitor 220 on a third substrate 600.

The semiconductor device may further include third and fourth bonding layers 490 and 730, first and second bonding pads 510 and 750 and first to seventh insulating interlayers 170, 230, 460, 480, 650, 660 and 700.

The third substrate 600 may include a semiconductor material, e.g., silicon, germanium, silicon-germanium, etc., or a III-V group compound semiconductor, e.g., GaP, GaAs, GaSb, etc. In example embodiments, the third substrate 600 may be a silicon-on-insulator (SOI) substrate or a germanium-on-insulator (GOI) substrate.

In example embodiments, the third substrate 600 may include a cell array region in which memory cells are formed and a peripheral circuit region in which peripheral circuit patterns are formed. The peripheral circuit region may at least partially surround the cell array region, and FIGS. 1 to 3 show the cell array region of the third substrate 600.

The semiconductor device may have a cell over periphery (COP) structure in which the memory cells are formed on the lower circuit pattern.

The lower circuit pattern may be a circuit pattern of a bit line sense amplifier (BLSA), sub-word line driver (SWD), column decoder, column select line (CSL) driver, input/output sense amplifier (I/O SA), write driver, etc. FIGS. 1 to 3 show the circuit pattern of the BLSA.

The lower circuit pattern may include, e.g., transistors, contact plugs, wirings, vias, etc.

The transistor may include a gate structure 630 on the third substrate 600 and source/drain layers 605 at upper portions of the third substrate 600 adjacent thereto.

The gate structure 630 may include a third gate insulation pattern 610 and a third gate electrode 620 sequentially stacked in the third direction D3. In an example embodiment, the gate structure 630 may extend in the second direction D2, and a plurality of gate structures 630 may be spaced apart from each other in the first direction D1. A gate spacer may be formed on each of opposite sidewalls of the gate structure 630.

The third gate insulation pattern 610 may include an oxide, e.g., silicon oxide, and the third gate electrode 620 may include a conductive material, e.g., a metal, a metal nitride, a metal silicide, doped polysilicon, etc.

Each of the source/drain layers 605 may include n-type impurities, e.g., phosphorus, arsenic, etc., or p-type impurities, e.g., boron, aluminum, etc.

In an example embodiment, the transistors may be formed at positions corresponding to the overlying bit lines 430, respectively.

The fifth insulating interlayer 650 may be formed on the third substrate 600, and may cover or overlap the transistor. The second contact plug 640 may extend through or into the fifth insulating interlayer 650, and may contact an upper surface of each of the source/drain layers 605.

The sixth insulating interlayer 660 may be formed on the fifth insulating interlayer 650 and the second contact plug 640. The first wiring 670, the first via 680 and the second wiring 690 may be formed in the sixth insulating interlayer 660, and may be sequentially stacked in the third direction D3. The first wiring 670 may contact an upper surface of the second contact plug 640.

The seventh insulating interlayer 700 may be formed on the sixth insulating interlayer 660 and the second wiring 690. The second via 710 and the third wiring 720 may be formed in the seventh insulating interlayer 700, and may be sequentially stacked in the third direction D3. The second via 710 may contact an upper surface of the second wiring 690.

The fourth bonding layer 730 may be formed on the seventh insulating interlayer 700 and the third wiring 720. The third contact plug 740 and the second bonding pad 750 may be formed in the fourth bonding layer 730, and may be sequentially stacked in the third direction D3. The third contact plug 740 may contact an upper surface of the third wiring 720.

The third bonding layer 490 may be formed on the fourth bonding layer 730 and the second bonding pad 750. The first bonding pad 510 may extend through or into a lower portion of the third bonding layer 490. The first contact plug 500 may extend through or into an upper portion of the third bonding layer 490 and the fourth insulating interlayer 480, and may contact an upper surface of the first bonding pad 510 and a lower surface of of the bit line 430.

The fourth insulating interlayer 480 may be formed on the third bonding layer 490.

Each of the fourth to seventh insulating interlayers 480, 650, 660 and 700 may include an oxide, e.g., silicon oxide or a low-k dielectric material, and each of the bonding layers 490 and 730 may include an insulating material, e.g., silicon carbonitride.

Each of the first and second bonding pads 510 and 750 may include a metal, e.g., copper, aluminum, etc. Each of the first to third contact plugs 640 and 740, the first to third wirings 670, 690 and 720, and the first and second vias 680 and 710 may include a conductive material, e.g., a metal, a metal nitride, a metal silicide, doped polysilicon, etc.

The bit line 430 may be formed on the fourth insulating interlayer 480.

The bit line 430 may extend in the second direction D2, and a plurality of bit line 430 may be spaced apart from each other in the first direction D1. The third insulating interlayer 460 may be disposed between neighboring ones of the bit lines 430 in the first direction D1, and a sidewall of each of the bit lines 430 may be covered or overlapped by the third insulating interlayer 460. The bit line 430 may include a conductive material, e.g., a metal, a metal nitride, a metal silicide, doped polysilicon, etc.

In example embodiments, a first portion of an upper surface of the bit line 430 that contacts a lower surface of the first gate structure 147 and a lower surface of the second gate structure 167 may be higher than a second portion of the upper surface of the bit line 430 that contacts a lower surface of the first contact 105. That is, the upper surface of the bit line 430 may have a varying height in the third direction D3.

A bit line shield may be further disposed between the neighboring ones of the bit lines 430 in the first direction D1.

The first and second gate structures 147 and 167 may be formed on the bit line 430 and the third insulating interlayer 460, respectively. Thus, each of the first and second gate structures 147 and 167 may extend in the first direction D1, and a plurality of first gate structures 147 may be spaced apart from each other in the second direction D2 and a plurality of second gate structures 167 may be spaced apart from each other in the second direction D2. In example embodiments, the first and second gate structures 147 and 167 may be alternately and repeatedly disposed in the second direction D2.

In example embodiments, a width in the second direction D2 of each of the first and second gate structures 147 and 167 may increase, for example, gradually in the third direction D3 away from an upper surface of the third substrate 600. That is, a cross-section in the second direction D2 of each of the first and second gate structures 147 and 167 may have a trapezoidal shape.

The first gate structure 147 may include a first capping pattern 135, a first gate electrode 140 and a second capping pattern 145 that are sequentially stacked in the third direction D3, and a first gate insulation pattern 130 that covers or overlaps opposite sidewalls in the second direction D2 of the first capping pattern 135, the first gate electrode 140 and the second capping pattern 145. The second gate structure 167 may include a third capping pattern 155, a second gate electrode 160 and a fourth capping pattern 165 that are sequentially stacked in the third direction D3, and a second gate insulation pattern 150 that covers or overlaps opposite sidewalls in the second direction D2 of the third capping pattern 155, the second gate electrode 160 and the fourth capping pattern 165.

Each of the first and third capping patterns 135 and 155 may extend in the first direction D1 on the bit line 430 and the third insulating interlayer 460. A plurality of first capping patterns 135 may be spaced apart from each other in the second direction D2, and a plurality of third capping patterns 155 may be spaced apart from each other in the second direction D2. In example embodiments, the first and third capping patterns 135 and 155 may be alternately and repeatedly disposed in the second direction D2. Each of the first and third capping patterns 135 and 155 may include an insulating nitride, e.g., silicon nitride, or an oxide, e.g., silicon oxide.

Each of the first and second gate electrodes 140 and 160 may extend in the first direction D1 on the first and third capping patterns 135 and 155, respectively. A plurality of first gate electrodes 140 may be spaced apart from each other in the second direction D2, and a plurality of second gate electrodes 160 may be spaced apart from each other in the second direction D2. In example embodiments, the first and second gate electrodes 140 and 160 may be alternately and repeatedly disposed in the second direction D2.

In example embodiments, the first gate electrode 140 may have a straight line shape extending in the first direction D1 in a plan view, while the second gate electrode 160 may include an extension portion extending in the first direction D1 and protrusion portions protruding or extending in the second direction D2 from each of opposite sidewalls in the second direction D2 in a plan view.

The first gate electrode 140 may include, e.g., doped polysilicon, and the second gate electrode 160 may include, e.g., a metal, a metal nitride, a metal silicide, etc. In example embodiments, the second gate electrode 160 may serve as a word line of the semiconductor device, and the first gate electrode 140 may serve as a back gate electrode of the semiconductor device.

The second and fourth capping patterns 145 and 165 may extend in the first direction D1 on the first and second gate electrodes 140 and 160, respectively. A plurality of second capping patterns 145 may be spaced apart from each other in the second direction D2, and a plurality of fourth capping patterns 165 may be spaced apart from each other in the second direction D2. In example embodiments, the second and fourth capping patterns 145 and 155 may be alternately and repeatedly disposed in the second direction D2. Each of the second and fourth capping patterns 145 and 165 may include an insulating nitride, e.g., silicon nitride, or an oxide, e.g., silicon oxide.

The first gate insulation pattern 130 may extend in the first direction D1 on the bit line 430 and the third insulating interlayer 460, and may cover or overlap opposite sidewalls in the second direction D2 of the first capping pattern 135, the first gate electrode 140 and the second capping pattern 145. Thus, a plurality of first gate insulation patterns 130 may be spaced apart from each other in the second direction D2.

The second gate insulation pattern 150 may extend in the first direction D1 on the bit line 430 and the third insulating interlayer 460, and may cover or overlap opposite sidewalls in the second direction D2 of the third capping pattern 155, the second gate electrode 160 and the fourth capping pattern 165. Thus, a plurality of second gate insulation patterns 150 may be spaced apart from each other in the second direction D2.

In example embodiments, the first gate insulation pattern 130 may have a straight line shape extending in the first direction D1 in a plan view, while the second gate insulation pattern 150 may extend in a zigzag pattern in the first direction D1 in a plan view. A sidewall of the second gate insulation pattern 150 may contact a portion of a sidewall of the first gate insulation pattern 130 corresponding thereto.

In an example embodiment, each of the first and second gate insulation patterns 130 and 150 may include an oxide, e.g., silicon oxide or an insulating nitride, e.g., silicon nitride. Alternatively, each of the first and second gate insulation patterns 130 and 150 may have a multi-layered structure including a first layer containing an oxide, e.g., silicon oxide and a second layer containing an insulating nitride, e.g., silicon nitride.

A plurality of contact structures 117 may be spaced apart from each other in the first and second directions D1 and D2. In example embodiments, the contact structures 117 may contact the upper surface of each of the bit lines 430 that extends in the second direction D2, and may be spaced apart from each other in the second direction D2.

In example embodiments, at least a portion of a sidewall of the contact structure 117 may be covered or overlapped by the first gate structure 147 or the second gate structure 167.

The contact structure 117 may include a first contact 105 and a second contact 115 sequentially stacked in the third direction D3. The first contact 105 may include, e.g., silicon doped with first impurities. The second contact 115 may include, e.g., silicon doped with second impurities. The second impurities may have a smaller diffusion coefficient than that of the first impurities. In example embodiments, the first impurities may include phosphorus, and the second impurities may include arsenic.

The channel 125 may be formed on each of the contact structures 117, and a plurality of channels 125 may be spaced apart from each other in the first and second directions D1 and D2.

A width in the second direction D2 of each of the contact structure 117 and the channel 125 may decrease, for example, gradually, in the third direction D3 away from the upper surface of the third substrate 600. That is, a cross-section in the second direction D2 of each of the contact structure 117 and the channel 125 may have an inverted trapezoidal shape.

In example embodiments, a sidewall in the second direction D2 of the channel 125 may contact the first gate insulation pattern 130, and an opposite sidewall in the second direction D2 and opposite sidewalls in the first direction D1 of the channel 125 may contact the second gate insulation pattern 150.

The channel 125 may include a semiconductor material, e.g., silicon, germanium, silicon-germanium, etc.

The first insulating interlayer 170 may be formed on the first and second gate structures 147 and 167 and the channel 125. The first insulating interlayer 170 may include an oxide, e.g., silicon oxide or a low-k dielectric material.

The landing pad 180 may extend through or into the first insulating interlayer 170, and may contact an upper surface of the channel 125. FIG. 3 shows that an area of a lower surface of the landing pad 180 is greater than an area of an upper surface of the channel 125, however, the present disclosure may not be limited thereto. Additionally, FIG. 1 shows that the landing pad 180 has a shape of a rectangle in a plan view, however, the present disclosure may not be limited thereto, and may have a shape of, e.g., a circle, an ellipse, a polygon with rounded corners, etc., in a plan view.

The landing pad 180 may include, e.g., a metal, a metal nitride, a metal silicide, etc.

The capacitor 220 may include a first capacitor electrode 190, a dielectric layer 200 and a second capacitor electrode 220.

In example embodiments, a plurality of first capacitor electrodes 190 may be spaced apart from each other in the first and second directions D1 and D2 to contact upper surfaces of corresponding landing pads 180, respectively. FIG. 1 shows that the first capacitor electrode 190 has a shape of a rectangle in a plan view, however, the present disclosure may not be limited thereto, and may have a shape of, e.g., a circle, an ellipse, a polygon with rounded corners, etc., in a plan view. Additionally, FIG. 1 shows that the first capacitor electrodes 190 are arranged in a lattice pattern in a plan view, however, the present disclosure may not be limited thereto, and may be arranged, e.g., in a honeycomb pattern in a plan view.

The first capacitor electrode 190 may include, e.g., a metal, a metal nitride, a metal silicide, etc., the dielectric layer 200 may include, e.g., a metal oxide, and the second capacitor electrode 210 may include, e.g., a metal, a metal nitride, a metal silicide, doped silicon-germanium, etc.

The second insulating interlayer 230 may be formed on the first insulating interlayer 170, and may cover or overlap the capacitor 220. The second insulating interlayer 230 may include an oxide, e.g., silicon oxide or a low-k dielectric material.

In the semiconductor device, a current may flow in the channel 125 in the third direction D3, that is, in the vertical direction between the bit line 430 and the landing pad 180, and thus the semiconductor device may include a vertical channel transistor (VCT) having a vertical channel.

In the semiconductor device, the second contact 115, which is doped with the second impurities with the diffusion coefficient smaller than the diffusion coefficient of the first impurities, may be interposed between the first contact 105, which is doped with the first impurities, and the channel 125. Thus, the first impurities diffusing into the channel 125 may be reduced or prevented, and the electrical characteristics of the channel 125 may be increased.

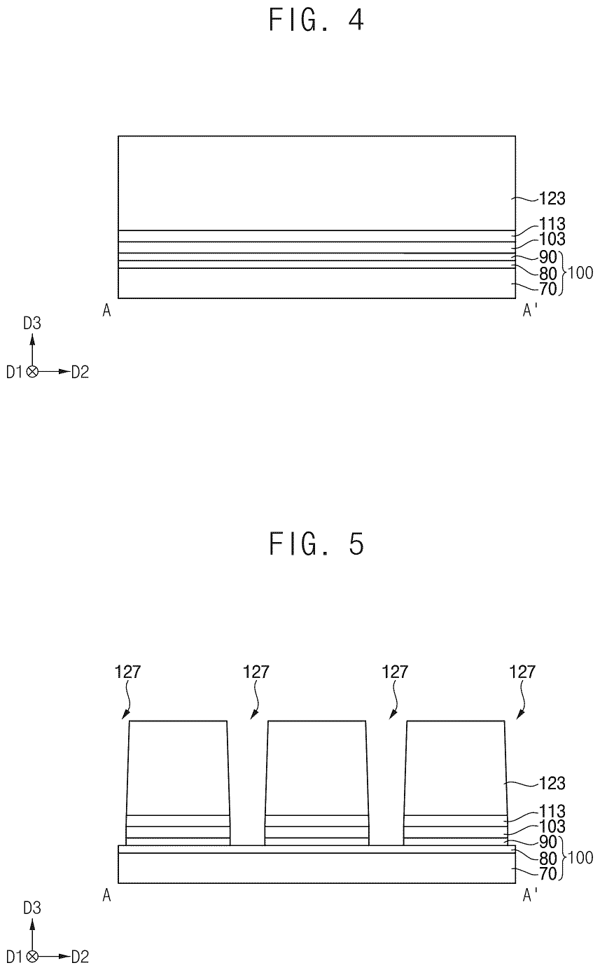

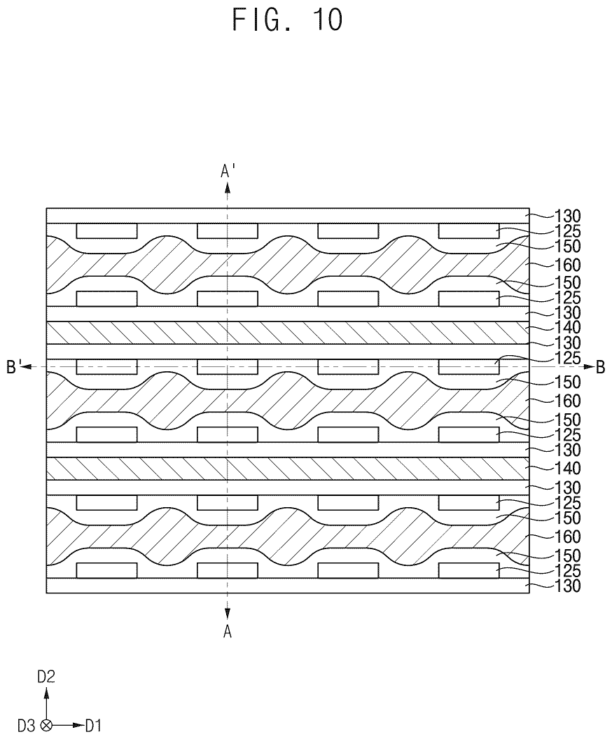

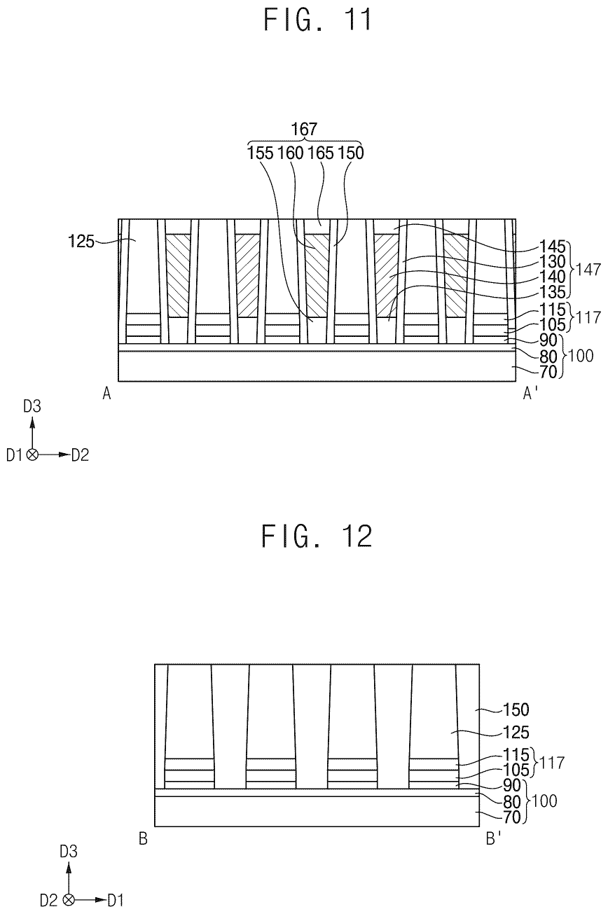

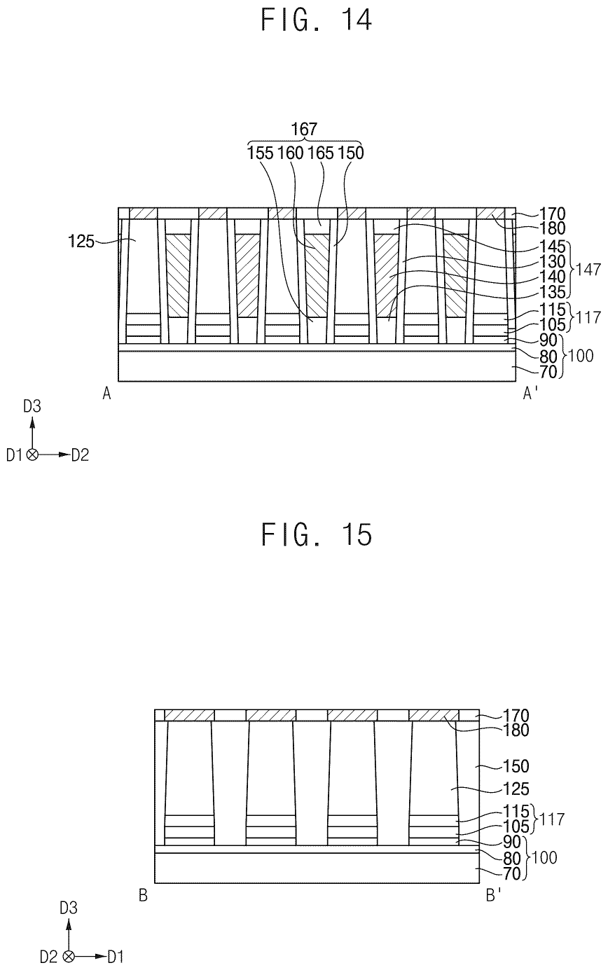

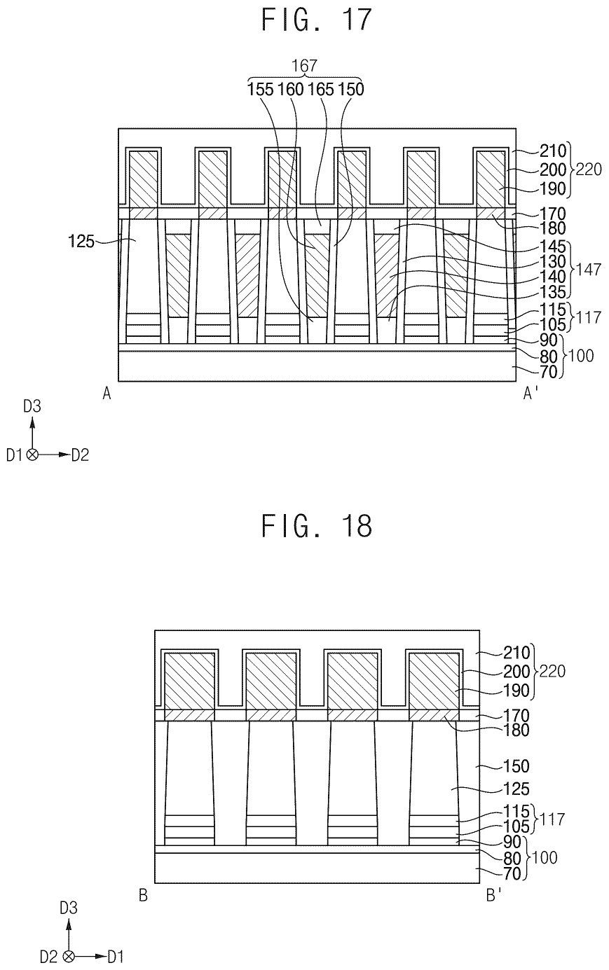

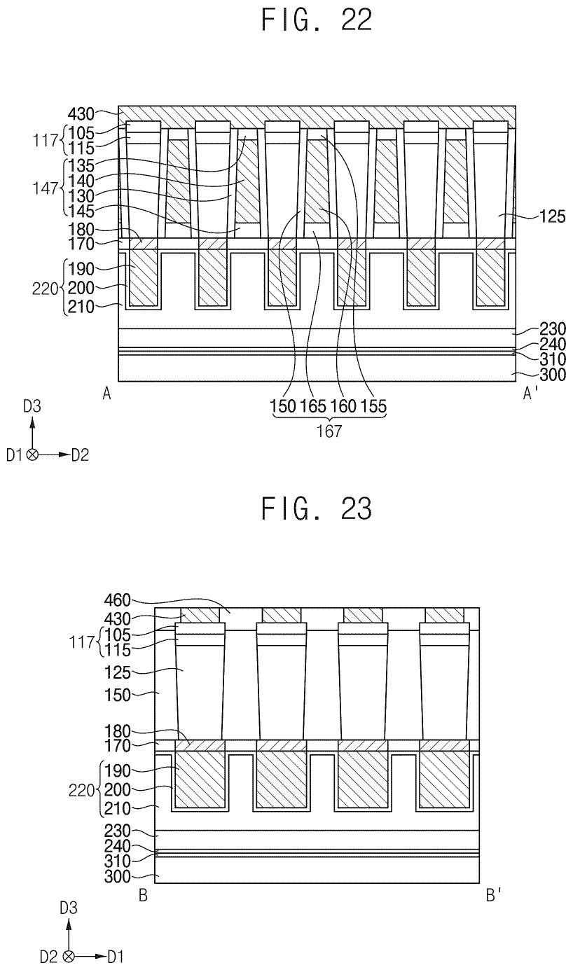

FIGS. 4 to 27 are plan views and cross-sectional views illustrating a method of manufacturing a semiconductor device in accordance with example embodiments.

Specifically, FIGS. 4, 6, 10, 13, 16 and 21 are the plan views, and FIGS. 5, 7, 8, 11, 14, 17, 19, 22, 24 and 26 are cross-sectional views taken along lines A-A′ of corresponding plan views, respectively, and FIGS. 9, 12, 15, 18, 20, 23, 25 and 27 are cross-sectional views taken along lines B-B′ of corresponding plan views, respectively.

Referring to FIG. 4, an epitaxial growth process may be performed on a first substrate 100 including a first bulk 70, a buried oxide layer 80 and a second bulk 90, and a preliminary first contact 103, a preliminary second contact 113 and a preliminary channel 123 may be sequentially formed.

The preliminary first contact 103 may be formed by a first epitaxial growth process using an upper surface of the second bulk 90 as a seed. The first epitaxial growth process may be performed by using a silicon source gas, e.g., dichlorosilane (SiH₂Cl₂) gas, and a source gas of first impurities, e.g., n-type impurities such as phosphorus. Accordingly, a silicon layer doped with the first impurities may be formed as the preliminary first contact 103.

The preliminary second contact 113 may be formed by a second epitaxial growth process using an upper surface of the preliminary first contact 103 as a seed. The second epitaxial growth process may be performed by using a silicon source gas, e.g., dichlorosilane (SiH₂Cl₂) gas, and a source gas of second impurities, e.g., n-type impurities such as arsenic. Accordingly, a silicon layer doped with the second impurities may be formed as the preliminary second contact 113. In example embodiments, a diffusion coefficient of the second impurities may be smaller than a diffusion coefficient of the first impurities.

A heat treatment process may be performed on the preliminary first and second contacts 103 and 113. Accordingly, resistance of the preliminary first and second contacts 103 and 113 may be reduced.

The preliminary channel 123 may be formed by a third epitaxial growth process using an upper surface of the preliminary second contact 113 as a seed. The third epitaxial growth process may be performed by using a silicon source gas, e.g., dichlorosilane (SiH₂Cl₂) gas.

Referring to FIG. 5, an etching process using the buried oxide layer 80 as an etch stop layer may be performed on the preliminary channel 123, the preliminary second contact 113 and the preliminary first contact 103 to form a first opening 127 that exposes an upper surface of the buried oxide layer 80.

Accordingly, each of the second bulk 90, the preliminary first contact 103, the preliminary second contact 113 and the preliminary channel 123 may be separated into a plurality of parts spaced apart from each other in the second direction D2, each of which extends in the first direction D1.

Due to the nature of the etching process, a width in the second direction D2 of each of the preliminary first contact 103, the preliminary second contact 113 and the preliminary channel 123 sequentially stacked on the buried oxide layer 80 may increase, for example, gradually, in the third direction D3 away from the upper surface of the buried oxide layer 80.

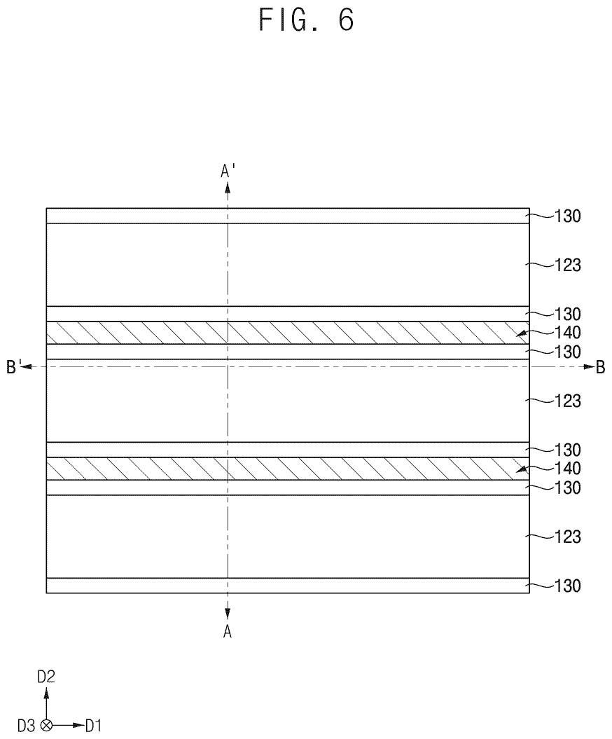

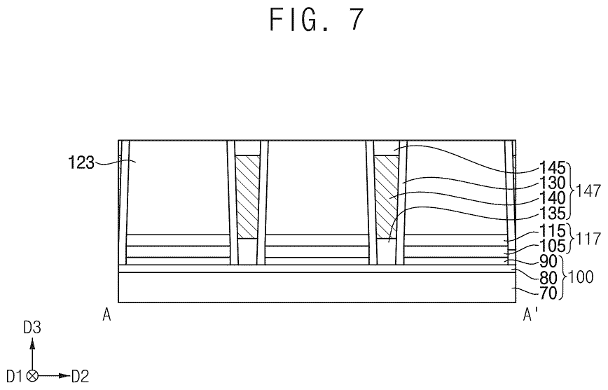

Referring to FIGS. 6 and 7, a first gate insulation pattern 130 may be formed on a sidewall of the first opening 127, and a first capping pattern 135, a first gate electrode 140 and a second capping pattern 145 may be formed to be sequentially stacked in the third direction D3 between the first gate insulation patterns 130.

In an example embodiment, the first gate insulation pattern 130 may be formed by forming a first gate insulation layer on the buried oxide layer 80, the second bulk 90, the preliminary first and second contacts 103 and 113 and the preliminary channel 123 by, e.g., an atomic layer deposition (ALD) process, and removing a portion of the first gate insulation layer on the upper surface of the buried oxide layer 80 and an upper surface of the preliminary channel 123 by an anisotropic etching process. In another example embodiment, the first gate insulation pattern 130 may be formed by an oxidation process on sidewalls of the second bulk 90, the preliminary first and second contacts 103 and 113 and the preliminary channel 123, and removing a portion of the first gate insulation layer on the upper surface of the preliminary channel 123.

In example embodiments, the preliminary channel 123 may extend in the first direction D1 along each of the opposite sidewalls in the second direction D2 of the second bulk 90, the preliminary first and second contacts 103 and 113 and the preliminary channel 123.

The first capping pattern 135 may be formed at a lower portion of the first opening 127 by forming a first capping layer on the preliminary channel 123, the first gate insulation pattern 130 and the buried oxide layer 80, and performing, e.g., an etch-back process on an upper portion of the first capping layer.

The first gate electrode 140 may be formed at a middle portion of the first opening 127 by forming a first gate electrode layer on the preliminary channel 123, the first gate insulation pattern 130 and the first capping pattern 135, and performing, e.g., an etch-back process on an upper portion of the first gate electrode layer.

The second capping pattern 145 may be formed by forming a second capping layer on the preliminary channel 123, the first gate insulation pattern 130 and the first gate electrode 140, and performing a planarization process on the second capping layer until an upper surface of the preliminary channel 123 is exposed.

The planarization process may include, e.g., a chemical mechanical polishing (CMP) process and/or an etch back process. During the planarization process, upper portions of the preliminary channel 123 and the first gate insulation pattern 130 may be partially removed.

In example embodiments, each of the first capping pattern 135, the first gate electrode 140 and the second capping pattern 145 may extend in the first direction D1 between the first gate insulation patterns 130. A plurality of first capping patterns 135 may be spaced apart from each other in the second direction D2, a plurality of first gate electrodes 140 may be spaced apart from each other in the second direction D2, and a plurality of second capping patterns 145 may be spaced apart from each other in the second direction D2.

The first capping pattern 135, the first gate electrode 140 and the second capping pattern 145 sequentially stacked in the third direction D3, and the first gate insulation pattern 130 disposed on opposite sidewalls in the second direction D2 of the first capping pattern 135, the first gate electrode 140 and the second capping pattern 145 may together form a first gate structure 147. In example embodiments, the first gate structure 147 may extend in the first direction D1, and a plurality of first gate structures 147 may be spaced apart from each other in the second direction D2.

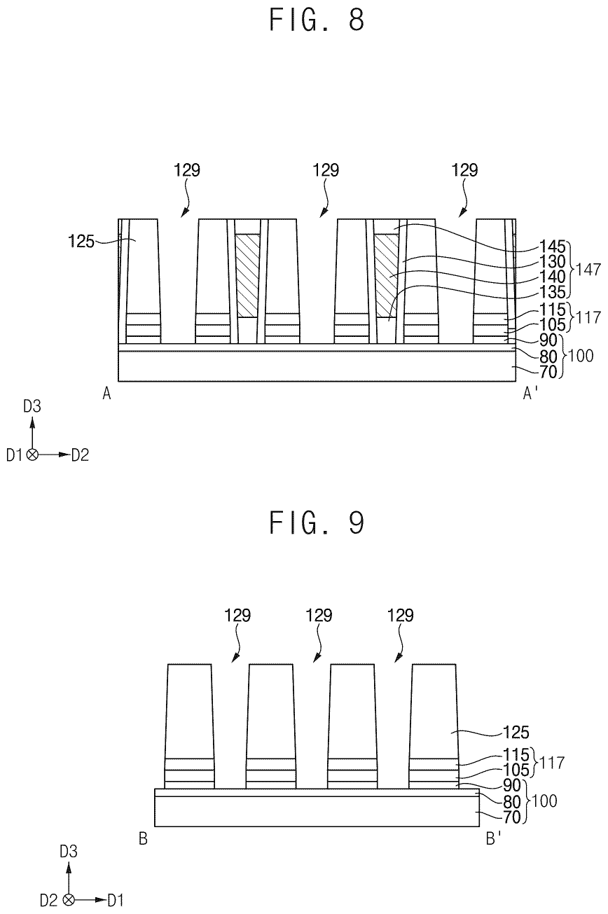

Referring to FIGS. 8 and 9, an etch mask may be formed to cover or overlap a portion of the first gate structure 147 and a portion of the preliminary channel 123, and an etching process using the etch mask may be performed to etch the preliminary channel 123, the preliminary second contact 113, the preliminary first contact 103 and the second bulk 90 to form a second opening 129 that exposed the upper surface of the buried oxide layer 80.

By the etching process, the second bulk 90 may be separated into a plurality of parts spaced apart from each other in the second direction D2, and the preliminary first contact 103, the preliminary second contact 113 and the preliminary channel 123 may be separated into a plurality of first contacts 105, a plurality of second contacts 115 and a plurality of channels 125, respectively. The first contact 105 and the second contact 115 may together form a contact structure 117.

In example embodiments, each of the contact structures 117 and the channels 125 may be spaced apart from each other in the first direction D1 along opposite sidewalls in the second direction D2 of the first gate insulation pattern 130.

Due to the nature of the etching process, a width in the second direction D2 of each of the contact structure 117 and the channel 125 sequentially stacked on the buried oxide layer 80, may decrease, for example, gradually, in the third direction D3 away from the upper surface of the buried oxide layer 80.

Referring to FIGS. 10 to 12, after removing the etch mask, a second gate insulation pattern 150 may be formed on sidewalls of the second bulk 90, the contact structure 117, the channel 125 and the first gate insulation pattern 130, and a third capping pattern 155, a second electrode 160 and a fourth capping pattern 165 may be formed to be sequentially stacked in the third direction D3 between the second gate insulation patterns 150.

The second gate insulation pattern 150, the third capping pattern 155, the second gate electrode 160 and the fourth capping pattern 165 may be formed by processes substantially the same as or similar to those for forming the first gate insulation pattern 130, the first capping pattern 135, the first gate electrode 140 and the second capping pattern 145, respectively.

The third capping pattern 155, the second gate electrode 160 and the fourth capping pattern 165 sequentially stacked in the third direction D3, and the second gate insulation pattern 150 disposed on opposite sidewalls in the second direction D2 of the third capping pattern 155, the second gate electrode 160 and the fourth capping pattern 165 may together form a second gate structure 167. In example embodiments, the second gate structure 167 may extend in the first direction D1, and a plurality of second gate structures 167 may be spaced apart from each other in the second direction D2.

In example embodiments, a plurality of channels 125 may be spaced apart from each other along the first direction D1 at each of opposite sidewalls in the second direction D2 of the second gate insulation pattern 150 that extends in the first direction D1.

In example embodiments, the second gate insulation pattern 150 may extend in a zigzag pattern in the first direction D1 in a plan view, instead of having a straight line extending in the first direction D1. In example embodiments, the second gate electrode 160 may include an extension portion extending in the first direction D1 and protrusion portions protruding or extending in the second direction D2 from each of opposite sidewalls in the second direction D2 of the extension portion.

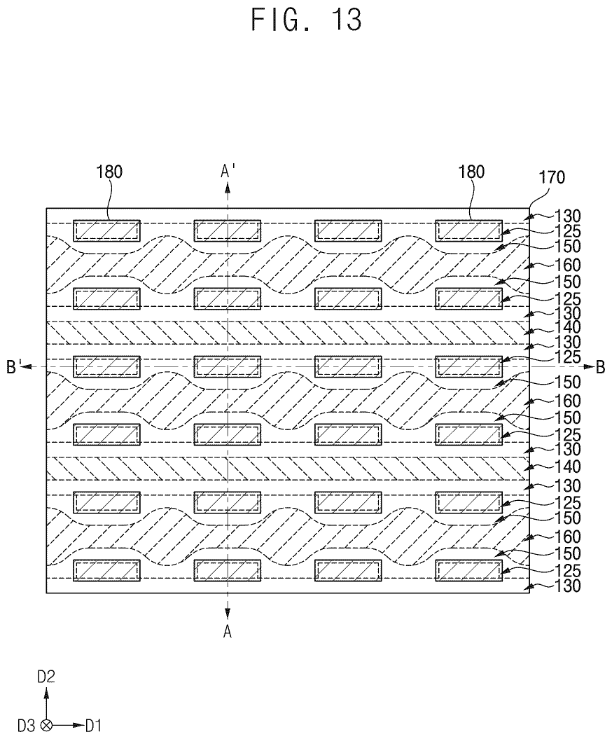

Referring to FIGS. 13 to 15, a first insulating interlayer 170 may be formed on the first and second gate structures 147 and 167 and the channel 125, and a landing pad 180 may be formed through or in the first insulating interlayer 170 to contact the upper surface of the channel 125.

In example embodiments, a plurality of landing pads 180 may be spaced apart from each other in the first and second directions D1 and D2, and may contact the upper surfaces of the corresponding channels 125, respectively.

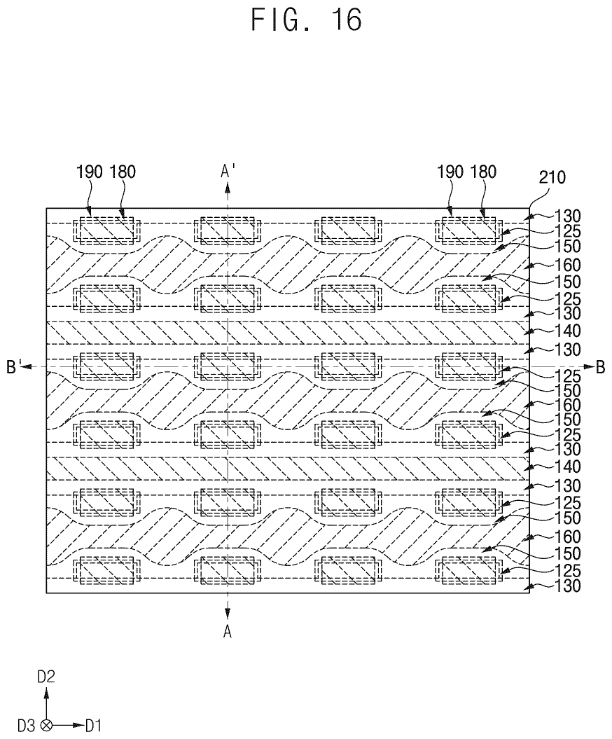

Referring to FIGS. 16 to 18, a first capacitor electrode 190 may be formed on the first insulating interlayer 170 and the landing pad 180 to contact an upper surface of the landing pad 180, a dielectric layer 200 may be formed on the first capacitor electrode 190, the landing pad 180 and the first insulating interlayer 170, and a second capacitor electrode 210 may be formed on the dielectric layer 200.

In example embodiments, a plurality of first capacitor electrodes 190 may be spaced apart from each other in the first and second directions D1 and D2, and may contact the upper surfaces of the corresponding landing pads 180, respectively.

The first capacitor electrode 190, the dielectric layer 200 and the second capacitor electrode 210 may collectively form a capacitor 220.

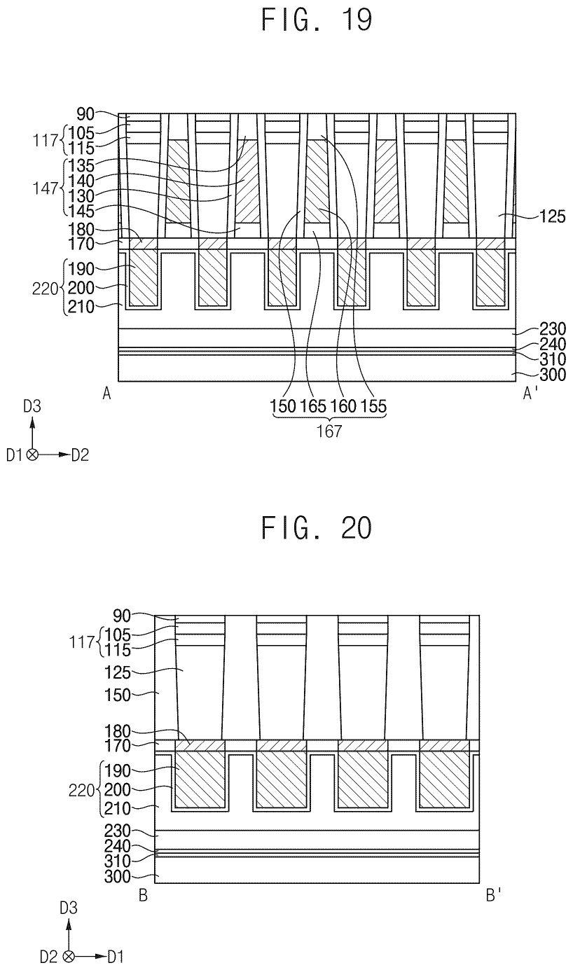

Referring to FIGS. 19 to 20, a second insulating interlayer 230 may be formed on the first insulating interlayer 170 to cover or overlap the capacitor 220, and a first bonding layer 240 may be formed on the first insulating interlayer 230.

Additionally, a second bonding layer 310 may be formed on a second substrate 300, the second substrate 300 may be overturned, and the second bonding layer 310 and the first bonding layer 240 may contact each other so that the first substrate structure and the second substrate 300 may be bonded with each other.

The first substrate 100 and the second substrate 300 bonded with each other may be overturned, and the first bulk 70 and the buried oxide layer 80 included in the first substrate structure may be removed, so that upper surfaces of the second bulk 90 and the first and second gate structures 147 and 167 may be exposed.

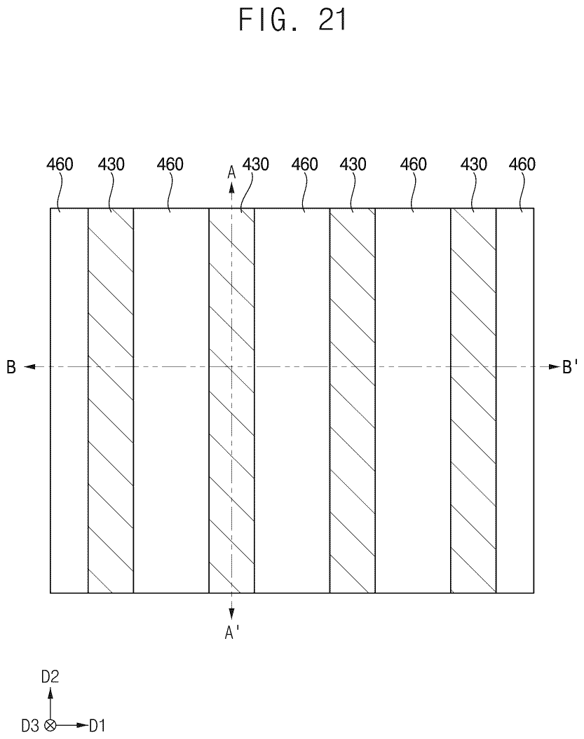

Referring to FIGS. 21 to 23, the second bulk 90, portions of the first and second gate insulation patterns 130 and 150 and portions the first and third capping patterns 135 and 155 may be removed by, e.g., a wet etching process, and a third insulating interlayer 460 may be formed thereon.

A portion of the third insulating interlayer 460 may be removed, a conductive layer may be formed on the first contact 105, and the first and third capping patterns 135 and 155 and the first and second gate insulation patterns 130 and 150 adjacent to the first contact 105 in the second direction D2, and a planarization process may be performed on an upper portion of the conductive layer until an upper surface of the third insulating interlayer 460 is exposed to form a bit line 430.

In example embodiments, the bit line 430 may extend in the second direction D2, and a plurality of bit lines 430 may be spaced apart from each other in the first direction D1.

A bit line shield extending in the second direction D2 may be further formed between neighboring ones of the bit lines in the first direction D1.

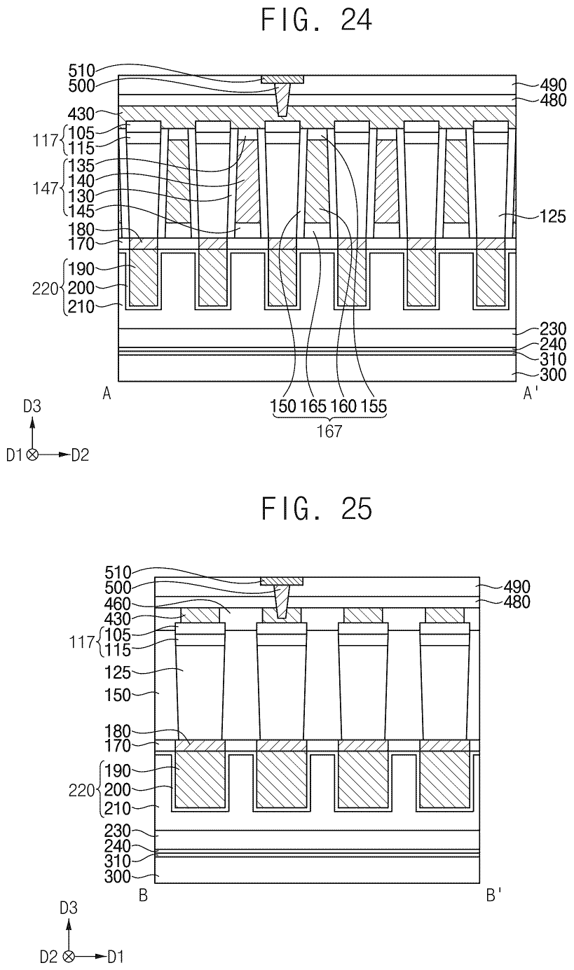

Referring to FIGS. 24 and 25, a fourth insulating interlayer 480 and a third bonding layer 490 may be formed on the bit line 430, and a first contact plug 500 extending through or into a lower portion of the third bonding layer 490 and the fourth insulating interlayer 480 to contact an upper surface of the bit line 430 and a first bonding pad 510 extending through or into an upper portion of the third bonding layer 490 to contact an upper surface of the first contact plug 500 may be formed.

In example embodiments, a plurality of first contact plugs 500 may be spaced apart from each other in the first direction D1 and a plurality of first bonding pads 510 may be spaced apart from each other the first direction D1.

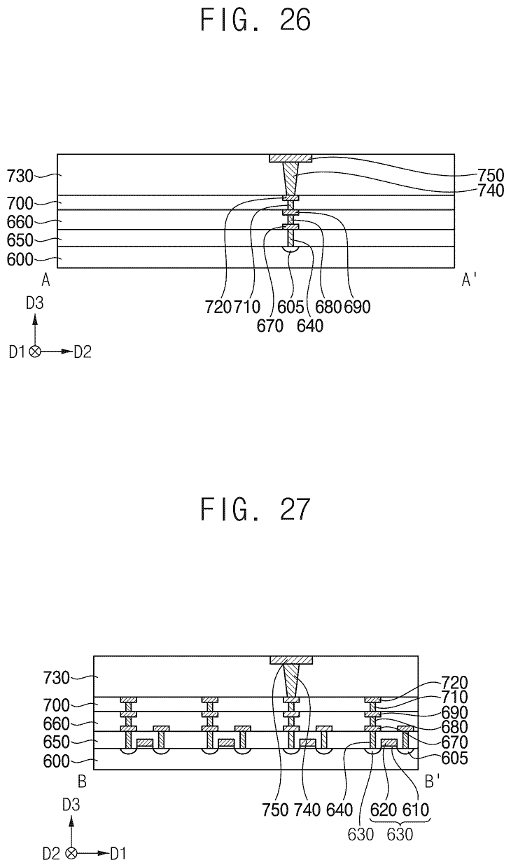

Referring to FIGS. 26 and 27, a transistor may be formed on a third substrate 600, a fifth insulating interlayer 650 may be formed on the third substrate 600 to cover or overlap the transistor, and a second contact plug 640 may be formed through the fifth insulating interlayer 650.

The transistor may include a gate structure 630 on the third substrate 600 and source/drain layers 605 at upper portions, respectively, of the third substrate 600 adjacent to the gate structure 630. The gate structure 630 may include a third gate insulation pattern 610 and a third gate electrode 620 that are sequentially stacked.

A sixth insulating interlayer 660, a first wiring 670, a first via 680 and a second wiring 690 may be formed on the fifth insulating interlayer 650 and the second contact plug 640.

A seventh insulating interlayer 700, a second via 710 and a third wiring 720 may be formed on the sixth insulating interlayer 660 and the second wiring 690.

A fourth bonding layer 730, a third contact plug 740 and a second bonding pad 750 may be formed on the seventh insulating interlayer 700 and the third wiring 720.

Referring to FIGS. 1 to 3, the third substrate 600 may be overturned, and the third and fourth bonding layers 490 and 730 may contact each other so that the third substrate 600 may be bonded with the first substrate structure and the second substrate 300.

In example embodiments, a lower surface of the second bonding pad 750 in the fourth bonding layer 730 may contact an upper surface of the first bonding pad 510 in the third bonding layer 490.

The first substrate structure and the second and third substrates 300 and 600 bonded with each other may be overturned, and the second substrate 300 and the first and second bonding layers 240 and 310 may be removed to complete the fabrication of the semiconductor device.

In the method for forming the semiconductor device, the preliminary first and second contacts 103 and 113 may be formed on the first substrate 100 by the first and second epitaxial growth processes, respectively, the heat treatment process may be performed on the preliminary first and second contacts 103 and 113, the preliminary channel 123 may be formed by the third epitaxial growth process, the first and second gate structures 147 and 167 may be formed in the first and second openings 127 and 129, respectively, which are formed by etching the preliminary channel 123, the capacitor 220 electrically connected to the channel 125 may be formed, and the first substrate 100 may be overturned. Thereafter, the bit line 430 that is electrically connected to channel 125 through the contact structure 117 may be formed.

If the contact structure 117 is formed after forming the capacitor 220 and overturing the first substrate 100, the characteristic of the capacitor 220 may be deteriorated due to the heat treatment process involved in the processes for forming the contact structure 117. In addition, if the contact structure 117 is formed by an epitaxial growth process that uses the channel 125 which has a relatively small surface, defects may occur during subsequent processes due to, for example, a (111) crystal plane of the contact structure 117.

However, in the method for forming the semiconductor device according to example embodiments, the contact structure 117 may be formed prior to forming the capacitor 220, and thus deterioration of the capacitor 220 due to the heat treatment process may be prevented or inhibited. In addition, each of the preliminary first and second contacts 103 and 113 may be formed in a plate shape, which has a relatively large surface area, and the preliminary first and second contacts 103 and 113 may be etched to form the first and second contacts 105 and 115. Thus, the contact structure 117 may not include, for example, a (111) crystal plane, and defects may not occur during subsequent processes.

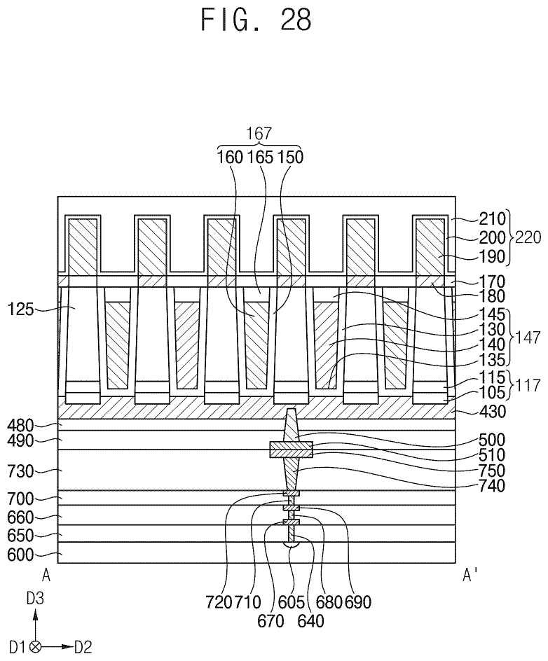

FIG. 28 is a cross-sectional view illustrating a semiconductor device in accordance with example embodiments. The semiconductor devices may be substantially the same as or similar to that of FIGS. 1 to 3, except for not including the first and third capping patterns 135 and 155, and shapes of the first and second gate insulation patterns 130 and 150.

Referring to FIG. 28, the first gate insulation pattern 130 may cover or overlap not only the sidewall but also a lower surface of the first gate electrode 140, and the second gate insulation pattern 150 may cover or overlap not only the sidewall but also a lower surface of the second gate electrode 160.

In example embodiments, the first and second gate insulation patterns 130 and 150 illustrated with reference to FIG. 28 may be formed by performing the ALD process to form the first and second gate insulation layers, but not the anisotropic etching process of FIGS. 6-7 and FIGS. 10 to 12.

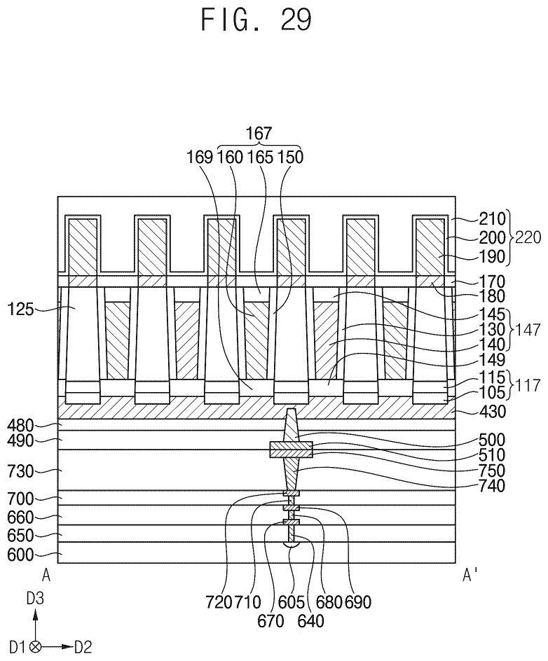

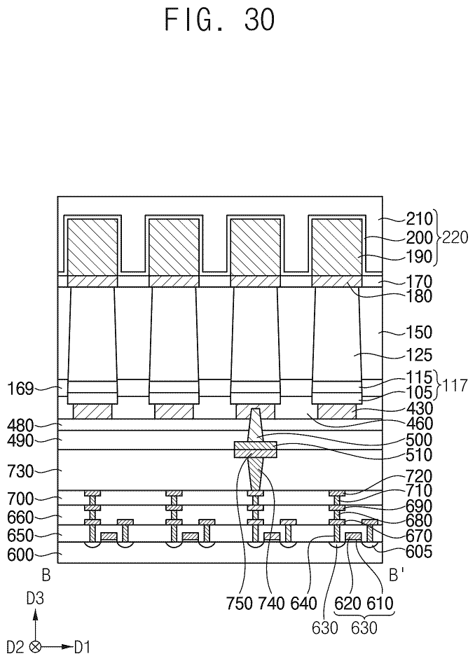

FIGS. 29 and 30 are cross-sectional views illustrating a semiconductor device in accordance with example embodiments. The semiconductor devices may be substantially the same as or similar to that of FIGS. 1 to 3, except for not including the first and third capping patterns 135 and 155, and further including a first buried pattern 149 and a second buried pattern 169.

Referring to FIGS. 29 and 30, each of the first and second buried patterns 149 and 169 may extend in the first direction D1 on the bit line 430 and the fourth insulating interlayer 480, a plurality of first buried patterns 149 may be spaced apart from each other in the second direction D2, and a plurality of second buried patterns 169 may be spaced apart from each other in the second direction D2.

In example embodiments, the first and second buried patterns 149 and 169 may be alternately and repeatedly disposed in the second direction D2. Each of the first and second buried patterns 149 and 169 may include an insulating nitride, e.g., silicon nitride, or an oxide, e.g., silicon oxide. The first and second gate electrodes 140 and 160 may be formed on the first and second buried patterns 149 and 169, respectively.

In example embodiments, the first and second buried patterns 149 and 169 may cover or overlap the sidewall of the contact structure 117. Accordingly, the first and second gate structures 147 and 167 may not contact the sidewall of the contact structure 117.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A semiconductor device comprising:
a bit line on a substrate, the bit line extending in a first direction substantially parallel to an upper surface of the substrate;
a channel on the bit line, the channel extending in a third direction substantially perpendicular to the upper surface of the substrate;
a first gate structure on a first sidewall of the channel, the first gate structure extending in a second direction, the second direction substantially parallel to the upper surface of the substrate and intersecting the first direction;
a contact structure between the bit line and the channel, the contact structure contacting the bit line and the channel, the contact structure comprising:
a first contact comprising a semiconductor material doped with first impurities, the first impurities comprising a first diffusion coefficient; and
a second contact on the first contact, the second contact contacting the first contact, the second contact comprising a semiconductor material doped with second impurities, the second impurities comprising a second diffusion coefficient, the second diffusion coefficient being less than the first diffusion coefficient; and
a capacitor on and electrically connected to the channel.

2. The semiconductor device according to claim 1, wherein the first impurities comprise phosphorous, and the second impurities comprise arsenic.

3. The semiconductor device according to claim 1, wherein a width of the channel in the first direction decreases from the upper surface of the substrate towards the capacitor.

4. The semiconductor device according to claim 1, wherein a width of the contact structure in the first direction decreases from the upper surface of the substrate towards the capacitor.

5. The semiconductor device according to claim 1, wherein a width of the first gate structure in the first direction increases from the upper surface of the substrate towards the capacitor.

6. The semiconductor device according to claim 1, further comprising a second gate structure on a second sidewall of the channel and extending in the second direction, the first and second sidewalls of the channel facing each other in the first direction.

7. The semiconductor device according to claim 6, wherein the first gate structure comprises silicon doped with impurities, and wherein the second gate structure comprises a metal, a metal nitride or a metal silicide.

8. The semiconductor device according to claim 1, wherein the first gate structure comprises:
a first gate electrode extending in the first direction; and
a gate insulation pattern on a sidewall of the first gate electrode, the gate insulation pattern contacting the first sidewall of the channel.

9. The semiconductor device according to claim 8, wherein a lower surface of the gate insulation pattern is separated from a lower surface of the substrate by a first distance, and wherein a lower surface of the first gate electrode is separated from the lower surface of the substrate by a second distance that is greater than the first distance.

10. The semiconductor device according to claim 8, wherein the gate insulation pattern contacts a portion of a sidewall of the contact structure.

11. The semiconductor device according to claim 8, wherein the gate insulation pattern overlaps a lower surface of the first gate electrode in the third direction.

12. The semiconductor device according to claim 1, wherein a portion of an upper surface of the bit line that contacts the first gate structure is separated from a lower surface of the substrate by a first distance, and wherein a portion of the upper surface of the bit line that contacts the contact structure is separated from the lower surface of the substrate by a second distance that is less than the first distance.

13. A semiconductor device comprising:
a bit line on a substrate, the bit line extending in a first direction substantially parallel to an upper surface of the substrate;
a contact structure on the bit line, the contact structure comprising a first contact and a second contact that contact each other, the first contact comprising a first semiconductor material doped with first impurities, the second contact comprising a second semiconductor material doped with second impurities, the first and second impurities being different from each other;
a channel on and contacting the contact structure;
a first gate structure on a first sidewall of the channel and a second gate structure on a second sidewall of the channel, each of the first gate structure and the second gate structure extending in a second direction substantially parallel to the upper surface of the substrate and intersecting the first direction; and
a capacitor on and electrically connected to the channel,
wherein a width of the contact structure in the first direction decreases from the upper surface of the substrate towards the capacitor, and
wherein a width of the channel in the first direction decreases from the upper surface of the substrate towards the capacitor.

14. The semiconductor device according to claim 13, wherein a width of each of the first gate structure and the second gate structure in the first direction increases from the upper surface of the substrate towards the capacitor.

15. The semiconductor device according to claim 13, wherein the first semiconductor material comprises silicon and the first impurities comprise phosphorous, and wherein the second semiconductor material comprises silicon and the second impurities comprise arsenic.

16. The semiconductor device according to claim 13, wherein each of the first gate structure and the second gate structure comprises:
a gate electrode extending in the first direction; and
a gate insulation pattern on a sidewall of the gate electrode, the gate insulation pattern contacting a respective sidewall of the channel.

17. The semiconductor device according to claim 16, wherein a lower surface of the gate insulation pattern is separated from a lower surface of the substrate by a first distance, and wherein a lower surface of the gate electrode is separated from the lower surface of the substrate by a second distance that is greater than the first distance.

18. The semiconductor device according to claim 16, wherein the gate insulation pattern contacts a portion of a sidewall of the contact structure.

19. A semiconductor device comprising:
a bit line on a substrate, the bit line extending in a first direction substantially parallel to an upper surface of the substrate;
a contact structure on the bit line, the contact structure comprising:
a first contact comprising a semiconductor material doped with first impurities comprising a first diffusion coefficient; and
a second contact on and contacting the first contact, the second contact comprising a semiconductor material doped with second impurities comprising a second diffusion coefficient that is less than the first diffusion coefficient;
a channel on and contacting the contact structure, the channel extending in a vertical direction substantially perpendicular to the upper surface of the substrate;
a first gate structure and a second gate structure on a first sidewall and a second sidewall of the channel, respectively, the first and second sidewalls of the channel facing each other in the first direction, each of the first gate structure and the second gate structure extending in a second direction substantially parallel to the upper surface of the substrate and intersecting the first direction; and
a capacitor on and electrically connected to the channel.

20. The semiconductor device according to claim 19, further comprising a plurality of bit lines, a plurality of first gate structures, a plurality of second gate structures, and a plurality of channels, wherein:
the plurality of bit lines comprise the bit line and are spaced apart from each other in the second direction,
the plurality of first gate structures comprise the first gate structure and are spaced apart from each other in the first direction,
the plurality of second gate structures comprise the second gate structure and are spaced apart from each other in the first direction,
the plurality of first gate structures and the plurality of second gate structures are alternately spaced apart from each other in the first direction, and
the plurality of channels comprise the channel, and
the plurality of channels are spaced apart from each other in the first direction and are on respective ones of the plurality of bit lines.
